(19) United States
(12) Patent Application Publication
(10) Pub. No.: US 2024/0128718 A1
(43) Pub. Date: Apr. 18, 2024

(54) OPTICAL DEVICE

(71) Applicant: Nippon Telegraph and Telephone Corporation, Tokyo (JP)

(72) Inventors: Masato Takiguchi, Tokyo (JP); Masaya Notomi, Tokyo (JP); Naotomo Takemura, Tokyo (JP); Akihiko Shinya, Tokyo (JP)

(21) Appl. No.: 18/547,253

(22) PCT Filed: Mar. 5, 2021
(86) PCT No.: PCT/JP2021/008632

§ 371 Date: Aug. 21, 2023

(51) Int. Cl. H01S 5/11; H01S 5/024; H01S 5/10

(52) U.S. Cl. CPC H01S 5/11; H01S 5/024; H01S 5/1003

(57) ABSTRACT

An optical device includes a photonic crystal main unit, an optical waveguide, an active region, an active substance, and a light source. The active region is formed in the optical waveguide and accommodates the liquid active substance formed with a four-level light-emitting material. For example, an accommodating unit formed in the active region is provided, and the active substance is accommodated in the accommodating unit. The active substance can be formed with an aqueous solution of a dye such as rhodamine, for example.

### CROSS-REFERENCE TO RELATED APPLICATIONS

This application is a national phase entry of PCT Application No. PCT/JP2021/008632, filed on Mar. 5, 2021, which application is hereby incorporated herein by reference.

### TECHNICAL FIELD

The present invention relates to an optical device that uses a four-level light-emitting material.

### BACKGROUND

These days, studies are being actively conducted to integrate compound semiconductor nanolasers in an optical circuit on a CMOS, with on-chip ultra-small sensors, optical processors, and quantum information applications being taken into consideration. Research has been conducted on wafer bonding of different materials and technologies for growing compound semiconductors directly on a silicon substrate, as methods for integrating nanolasers. These methods limit the materials that can be bonded and the materials that can be grown on a substrate, but studies on direct transfer of completely arbitrary materials are also being actively conducted. For example, nanomaterials can be integrated on an optical substrate by various methods involving a transfer printing technique, an inkjet technique, a microneedle, an atomic force microscope, or the like.

Since an optical element as a transfer destination is very small and has a very high degree of freedom in optical design, a photonic crystal that enables great optical confinement is useful. If the design is appropriately made, a nanomaterial and an optical electric field can be made to strongly interact with each other. By such a technology, high-quality compound semiconductors or desired nanomaterials can be selectively integrated on a silicon chip, and applications such as development of new elements can be expected. For example, compound semiconductor nanowires are transferred onto a silicon photonic crystal, and very small nanomaterials can be precisely integrated by the above-described nano-control technology these days (Non Patent Literature 1 and Non Patent Literature 2).

### CITATION LIST

### Non Patent Literature

Non Patent Literature 1: M. NOTOMI et al., “Nanowire photonics toward wide wavelength range and subwavelength confinement [Invited]”, Optical Materials Express, vol. 10, no. 10, pp. 2560-2596, 2020.
Non Patent Literature 2: M. Takiguchi et al., “Continuous-wave operation and 10-Gb/s direct modulation of InAsP/InP subwavelength nanowire laser on silicon photonic crystal”, APL Photonics, vol. 2, no. 4,046106, 2017.

### SUMMARY

### Technical Problem

Meanwhile, lasers in which semiconductor nanomaterials are integrated in a photonic crystal have been studied by a nano-manipulation technology or the like, but these lasers have the following problem. Normally, the shape of a nanowire greatly affects the crystal structure. A nanowire has a polygonal or circular cross-section, does not form a perfect pillar structure, and has a tapered shape. Such a disproportionate structure generates a small space between the nanowires and the substrate when integrated in a photonic crystal, and causes electric field leakage into the air. Therefore, light cannot be efficiently confined in the nanowires serving as the active portion. As described above, by the conventional technologies, light cannot be efficiently confined in an active portion provided in a photonic crystal.

Embodiments of the present invention have been made to solve the above problem, and aim to enable efficient optical confinement in an active portion formed in a photonic crystal.

### Solution to Problem

An optical device according to embodiments of the present invention includes: a plate-like photonic crystal main unit that includes a base unit and a plurality of columnar lattice elements formed in and/or on the base unit, the lattice elements being periodically arranged at an interval not longer than a wavelength of target light, and the lattice elements having a different refractive index from a refractive index of the base unit; an optical waveguide provided in the photonic crystal main unit, the optical waveguide being formed with a linear line defect that includes a plurality of defects formed with portions not including the lattice elements; an active region formed in the optical waveguide; a liquid active substance that is disposed in the active region, and is formed with a four-level light-emitting material; a light source that excites the active substance; and an optical confinement structure that confines light in the active region, the active region being interposed between the optical waveguide and the optical confinement structure.

### Advantageous Effects of Embodiments of the Invention

As described above, according to embodiments of the present invention, a liquid active substance formed with a four-level light-emitting material is disposed in an active region provided in an optical waveguide formed with line defects of a photonic crystal, so that light can be efficiently confined in the active portion formed in the photonic crystal.

### BRIEF DESCRIPTION OF THE DRAWINGS

FIG. 1A is a configuration diagram illustrating the configuration of an optical device according to a first embodiment of the present invention.

FIG. 1B is a perspective view of part of the configuration of the optical device according to the first embodiment of the present invention.

FIG. 2 is a configuration diagram illustrating the configuration of an optical device according to a second embodiment of the present invention.

FIG. 3 is a plan view (a) and cross-sectional views (b) and (c) of part of the configuration of an optical device according to a third embodiment of the present invention.

FIG. 4 is a plan view of part of the configuration of an optical device according to a fourth embodiment of the present invention.

FIG. 5 is a plan view (a) and cross-sectional views (b) and (c) of part of the configuration of an optical device according to a fifth embodiment of the present invention.

FIG. 6 is a plan view of part of the configuration of an optical device according to a sixth embodiment of the present invention.

### DETAILED DESCRIPTION OF ILLUSTRATIVE EMBODIMENTS

The following is a description of optical devices according to embodiments of the present invention.

### First Embodiment

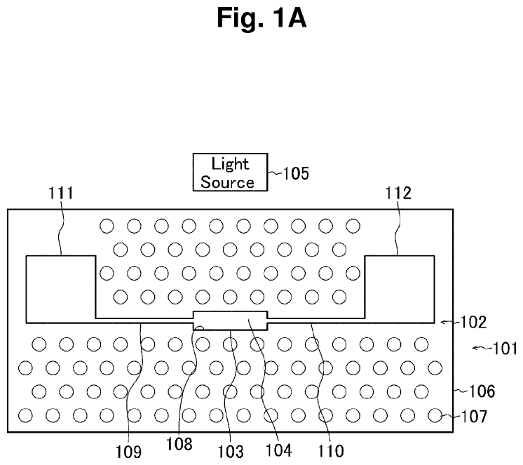

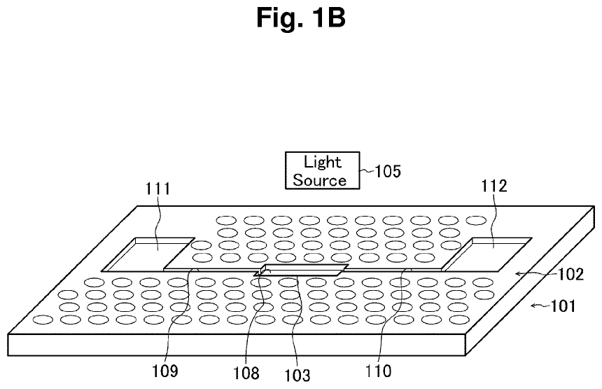

First, an optical device according to a first embodiment of the present invention is described with reference to FIGS. 1A and 1B. This optical device includes a photonic crystal main unit 101, an optical waveguide 102, an active region 103, an active substance 104, and a light source 105. Note that, in FIG. 1A, the photonic crystal main unit 101 shows a flat surface.

The photonic crystal main unit 101 includes a plate-like base unit 106. The photonic crystal main unit 101 also includes a plurality of lattice elements 107. The lattice elements 107 are periodically arranged at intervals equal to or shorter than the wavelength of the target light. Further, the lattice elements 107 have a different refractive index from that of the base unit 106. The base unit 106 can be formed with SiN, SiC, TiO₂, SiO₂, or the like, for example. The lattice elements 107 are cylindrical through holes, for example. The plurality of lattice elements 107 is arranged in a triangular lattice form in a planar view, for example. The optical waveguide 102 is provided in the photonic crystal main unit 101, and includes linear line defects formed with a plurality of defects that are portions without the lattice elements 107.

The active region 103 is formed in the optical waveguide 102. In the active region 103, the liquid active substance 104 formed with a four-level light-emitting material is disposed. For example, an accommodating unit 108 formed in the active region 103 is provided, and the active substance 104 is accommodated in the accommodating unit 108. The accommodating unit 108 is a recess formed in the active region 103 on a surface of the base unit 106, for example. In a planar view, the accommodating unit 108 is formed in the entire active region 103. Accordingly, it can also be said that the accommodating unit 108 is the active region 103. The accommodating unit 108 can also be formed on the base unit 106 in the active region 103. The accommodating unit 108 has a rectangular parallelepiped shape that is a rectangular shape in a planar view, for example. The accommodating unit 108 has a width and a depth that are substantially the same as the diameter of a so-called nanowire, in a direction perpendicular to the waveguide direction of the optical waveguide 102, for example.

The active substance 104 can be formed with an aqueous solution of a dye such as rhodamine, for example. This type of dye is a four-level light-emitting material, and is used in a large laser. The active substance 104 can also be formed with fine particles of a four-level light-emitting material and a dispersion medium in which the fine particles are dispersed. The fine particles of a four-level light-emitting material may be yttrium aluminum garnet (YAG), for example.

The light source 105 is used to excite the active substance 104. The light source 105 can be formed with a flash lamp or a laser, for example. The light source 105 can be disposed above the active region 103, for example. The active substance 104 accommodated in the accommodating unit 108 is irradiated, from above the active region 103, with excitation light emitted from the light source 105 disposed above the active region 103.

Also, the optical device according to the first embodiment has an optical confinement structure for confining light in the active region 103, the optical confinement structure being formed in the optical waveguide 102 with the active region 103 interposed in between. For example, a first flow path 109 for supplying the active substance 104 to the accommodating unit 108, and a second flow path 110 for discharging the active substance 104 supplied to the accommodating unit 108 can be provided.

The first flow path 109 and the second flow path 110 are formed in the optical waveguide 102, the flow direction of the first flow path 109 and the second flow path 110 is the waveguide direction of the optical waveguide 102, and the width of the first flow path 109 and the second flow path 110 is made narrower than the width perpendicular to the waveguide direction of the accommodating unit 108. With this configuration, an optical confinement structure for confining light in the active region 103 can be formed in the optical waveguide 102. With this optical confinement structure, a resonator with a photonic crystal can be formed.

According to the first embodiment, the active substance 104 is a liquid, and thus, the active region 103 (the accommodating unit 108) can be filled with the active substance 104 without any gap. As described above, according to the first embodiment, no gap is formed between the accommodating unit 108 and the active substance 104, and thus, the confinement factor can be improved unlike that with a laser using a nanowire.

Meanwhile, a conventional semiconductor nanolaser has a high transparent carrier density (Nₒ), and, even when the spontaneous emission high-coupling rate P of a nano-resonator is increased, the quadratic intensity correlation function g²(0)>1 at the oscillation threshold or lower, and coherent light is not obtained (Reference Literature 1). Note that the laser linewidth is the full width at half maximum of the laser spectrum. According to the first embodiment, on the other hand, the active substance 104 is formed with a four-level light-emitting material such as a dye. Accordingly, Nₒ is small, and β can be increased with a resonator formed with a photonic crystal. As a result, g₂(0)=1 even at the oscillation threshold or lower, and coherent light can be extracted.

Also, in the conventional semiconductor laser, the laser linewidth is thick, because of the α parameter. The a parameter is defined by the ratio of the increase rate (differential gain) of the optical gain and the increase rate of the refractive index with respect to the increase in the carrier density in the semiconductor. Since the carrier density in the semiconductor fluctuates due to various kinds of noise, the oscillation frequency of the semiconductor laser also fluctuates randomly, resulting in a decrease in coherence, which is an increase in oscillation linewidth. For this reason, it is known that the oscillation linewidth of the semiconductor laser is larger by one digit or more than that expected from a theoretical formula (Schawlow-Townes formula) expressing the oscillation linewidth of a normal laser, and the laser linewidth during steady current drive is (1+α²) times greater than the theoretical value.

On the other hand, in a case where a dye is used for the active substance 104, wavelength selectivity is high, and the α factor is small unlike a semiconductor material. Accordingly, a laser having a very narrow linewidth can be formed.

Meanwhile, an introduction pool structure 11 is connected to the first flow path 109, and a discharge pool structure 112 is connected to the second flow path 110, so that the active substance 104 can circulate in the accommodating unit 108, for example. For example, by attaching a tube such as a silicone rubber tube to the introduction pool structure 111, it is possible to introduce the liquid active substance 104 from the outside. Introduced into the introduction pool structure in, the liquid active substance 104 enters the first flow path 109 due to a so-called capillary action, and flows into the accommodating unit 108. When the active substance 104 that has flowed into the accommodating unit 108 reaches the second flow path 110, the active substance 104 enters the second flow path 110 due to a capillary action, and flows into the discharge pool structure 112.

As the first flow path 109 and the second flow path 110 that have such a flow path width as to cause a capillary action are used as described above, the active substance 104 can be automatically (naturally) introduced into the accommodating unit 108. Therefore, as long as the active substance 104 can be supplied into the introduction pool structure 11 with a micropipette, an inkjet device, or the like but without any structure for causing a liquid to circulate, the active substance 104 can be supplied to the accommodating unit 108 that is a resonant portion.

In the first embodiment, a temperature control unit that controls the temperature of the active substance 104 can be further provided. For example, the liquid temperature of the active substance 104 to be supplied to the introduction pool structure in can be controlled by the temperature control unit. As temperature control is performed in this manner, the temperature of the region (the active region 103) of the resonator with which the active substance 104 is brought into contact can be changed.

### Second Embodiment

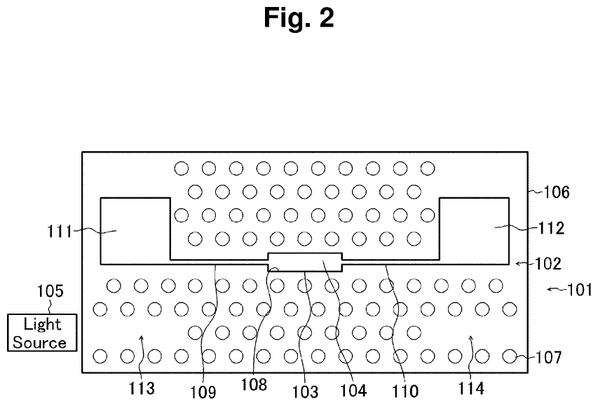

Next, an optical device according to a second embodiment of the present invention is described with reference to FIG. 2. This optical device includes a photonic crystal main unit 101, an optical waveguide 102, an active region 103, an active substance 104, a light source 105, and an optical confinement structure that serves as a resonator. These components are the same as those of the first embodiment described above.

In the second embodiment, an input optical waveguide 113 and an output optical waveguide 114 are further included. The input optical waveguide 113 and the output optical waveguide 114 are provided in the photonic crystal main unit 101, and includes linear line defects formed with a plurality of defects that are portions without the lattice elements 107. Also, the input optical waveguide 113 and the output optical waveguide 114 are arranged in parallel with the optical waveguide 102. Further, the active region 103 (the accommodating unit 108) is disposed in the optical waveguide 102 in the region interposed between the input optical waveguide 113 and the output optical waveguide 114.

In this optical device, excitation light emitted from the light source 105 is input to the input optical waveguide 113, and the excitation light being guided in the input optical waveguide 113 is optically coupled to the active substance 104 accommodated in the accommodating unit 108 to excite the active substance 104. Laser light oscillated by the excited active substance 104 is optically coupled to the output optical waveguide 114, and is emitted from the photonic crystal main unit 101. In the example described with reference to FIGS. 1A and 1B, the first flow path 109 and the second flow path 110 exist in the optical waveguide 102. Therefore, the device functions as a surface-emitting laser but cannot extract laser light on the same axis as the resonator. As a result, laser light cannot be emitted from an end face of the photonic crystal main unit 101. The same applies to introduction of excitation light. On the other hand, by providing the input optical waveguide 113 and the output optical waveguide 114 as described above, introduction of excitation light and emission of laser light can be conducted at the end faces of the photonic crystal main unit 101.

### Third Embodiment

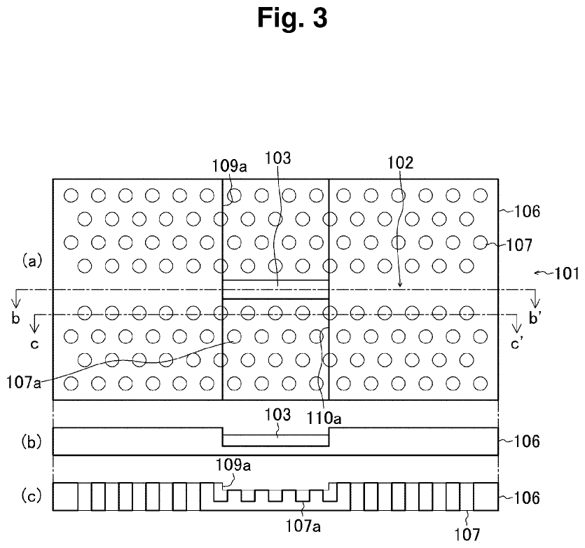

Next, an optical device according to a third embodiment of the present invention is described with reference to FIG. 3. This optical device includes a photonic crystal main unit 101, an optical waveguide 102, an active region 103a, an active substance 104, a light source 105, and an optical confinement structure that serves as a resonator. These components are the same as those of the first embodiment described above.

In the third embodiment, a first flow path 109a for supplying the active substance 104 to the accommodating unit 108, and a second flow path 110a for discharging the active substance 104 supplied to the accommodating unit 108 are arranged in a direction intersecting the waveguide direction of the optical waveguide 102. In this case, lattice elements 107a in each of the first flow path 109a and the second flow path 110a do not penetrate the base unit 106 but form recesses that reach only halfway in the thickness direction of the base unit 106, so that the liquid active substance 104 does not leak out.

### Fourth Embodiment

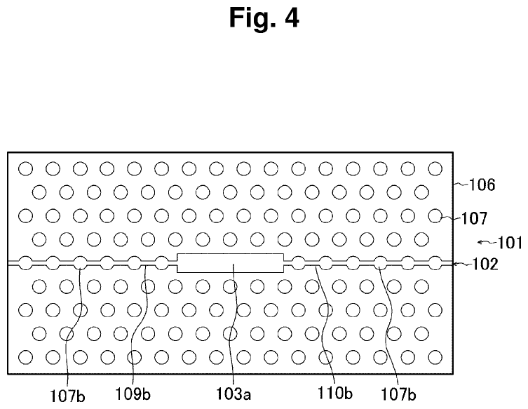

Next, an optical device according to a fourth embodiment of the present invention is described with reference to FIG. 4. This optical device includes a photonic crystal main unit 101, an optical waveguide 102, an active region 103, an active substance 104, a light source 105, and an optical confinement structure that serves as a resonator. These components are the same as those of the first embodiment described above.

In the fourth embodiment, lattice elements 107b in the same lattice array as the lattice elements 107 are provided in a first flow path 109b and a second flow path 110b that constitute the optical confinement structure. The lattice elements 107b do not penetrate the base unit 106 but form recesses that reach only halfway in the thickness direction of the base unit 106, so that the liquid active substance 104 does not leak out. As the lattice elements 107b are provided in this manner, the optical confinement by the optical confinement structure can be made stronger.

### Fifth Embodiment

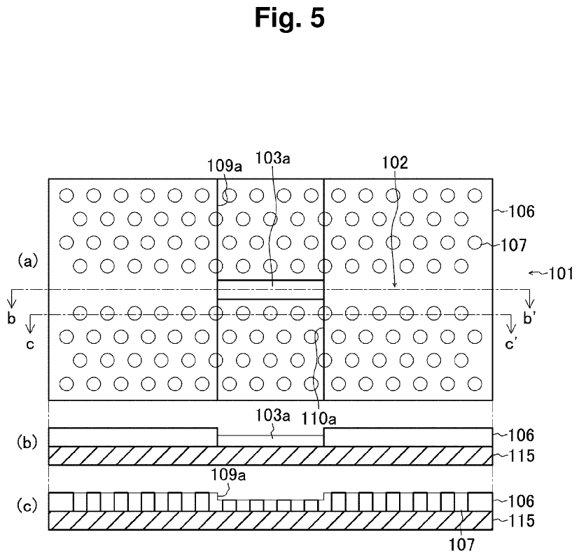

Next, an optical device according to a fifth embodiment of the present invention is described with reference to FIG. 5. This optical device includes a photonic crystal main unit 101, an optical waveguide 102, an active region 103a, an active substance 104, a light source 105, and an optical confinement structure that serves as a resonator. These components are the same as those of the first embodiment described above.

Also, in the fifth embodiment, a first flow path 109a for supplying the active substance 104 to the accommodating unit 108, and a second flow path 110a for discharging the active substance 104 supplied to the accommodating unit 108 are arranged in a direction intersecting the waveguide direction of the optical waveguide 102, as in the third embodiment described above.

In the fifth embodiment, a cladding layer 115 is further provided in contact with the lower surface of the base unit 106. The cladding layer 115 is formed with a material having a lower refractive index than that of the base unit 106. As the cladding layer 115 is provided in contact with the lower surface of the base unit 106 in this manner, the lattice elements 107 can be formed to penetrate the base unit 106 also in the first flow path 109a and the second flow path 110a. Since the back surface of the base unit 106 is covered with the cladding layer 115, leakage of the active substance 104 does not occur even though the penetrating lattice elements 107 are formed in the first flow path 109a and the second flow path 110a.

### Sixth Embodiment

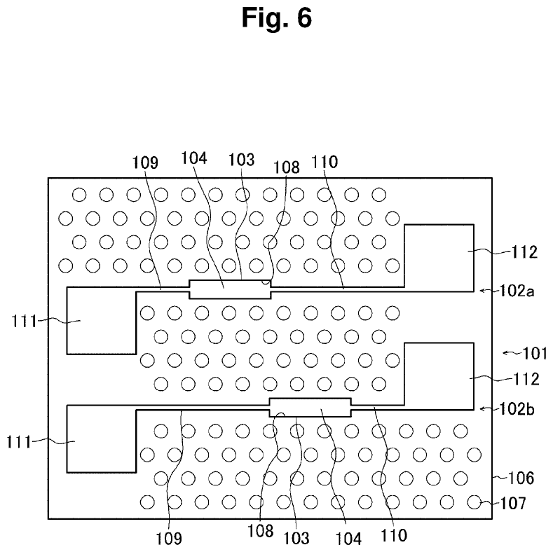

Next, an optical device according to a sixth embodiment of the present invention is described with reference to FIG. 6. This optical device includes two optical waveguides 102a and 102b. Further, an active region 103, an active substance 104, an accommodating unit 108, a first flow path 109, and a second flow path 110 are formed in each of the two optical waveguides 102a and 102b.

The respective resonators by an optical confinement region centered about the active substance 104 (the accommodating unit 108) in each of the two optical waveguides 102a and 102b are disposed in a couplable state, to constitute a coupled resonator. The temperature of the active substance 104 accommodated in each accommodating unit 108 can be individually controlled, and it is possible to change the coupling between resonators by changing each temperature. With this coupled resonator structure, wavelength control on two resonators, which has been difficult in a semiconductor laser that complicates the behavior of the system, can be easily performed, and can be applied to a coupled resonator laser, an injection-locked laser, and the like.

As described above, according to embodiments of the present invention, a liquid active substance formed with a four-level light-emitting material is disposed in an active region provided in an optical waveguide formed with line defects of a photonic crystal. Thus, light can be efficiently confined in the active portion formed in the photonic crystal. Embodiments of the present invention can be applied to decreases in power consumption of future on-chip elements, light sources for on-chip atomic clocks, and the like. Further, unlike a semiconductor material, an active substance can reduce the α factor, and accordingly, is effective in that its behavior is stabilized even in controlling an injection-locked laser or the like.

Note that it is obvious that the embodiments of the present invention are not limited to the embodiments described above, but can be modified and combined in many ways by a person having ordinary knowledge in the art within the technical idea of the embodiments of the present invention.
Reference Literature 1: N. Takemura et al., “Low- and high-β lasers in class-A limit: photon statistics, linewidth, and the laser-phase transition analogy”, Journal of the Optical Society of America B, Vol. 38, Issue 3, pp. 699-710, 2021.

### REFERENCE SIGNS LIST

101 photonic crystal main unit
102 optical waveguide
103 active region
104 active substance
105 light source
106 base unit
107 lattice element
108 accommodating unit
109 first flow path
110 second flow path
111 introduction pool structure
112 discharge pool structure

1.-7. (canceled)

8. An optical device comprising:
a plate-like photonic crystal main structure comprising a base substrate and a plurality of columnar lattice elements disposed in or on the base substrate, the lattice elements being periodically arranged at an interval not longer than a wavelength of a target light, and the lattice elements having a refractive index that is different from a refractive index of the base substrate;
an optical waveguide provided in the photonic crystal main structure, the optical waveguide comprising a linear line defect comprising a plurality of defects that are portions without the lattice elements;
an active region in the optical waveguide;
an active substance in a liquid state disposed in the active region and comprising a four-level light-emitting material;
a light source configured to excite the active substance; and
an optical confinement structure configured to confine light in the active region, wherein the active region is interposed between the optical waveguide and the optical confinement structure.

9. The optical device according to claim 8, wherein the active substance comprises fine particles of the four-level light-emitting material and a dispersion medium in which the fine particles are dispersed.

10. The optical device according to claim 8, further comprising a recess in the active region, wherein the active substance is accommodated in the recess.

11. The optical device according to claim 10, wherein the recess is on the base substrate in the active region.

12. The optical device according to claim 10, further comprising a flow path configured to supply the active substance into the recess.

13. The optical device according to claim 8, further comprising a temperature controller configured to control a temperature of the active substance.

14. The optical device according to claim 13, wherein:
the active region is provided in plural; and
the temperature controller is configured to control temperatures of the active substance in each of the active regions separately from one another.

15. An optical device comprising:
a plate-like photonic crystal main structure comprising a base substrate and a plurality of columnar lattice elements disposed in or on the base substrate, the lattice elements being periodically arranged at an interval not longer than a wavelength of a target light, and the lattice elements having a refractive index that is different from a refractive index of the base substrate;
an optical waveguide provided in the photonic crystal main structure, the optical waveguide comprising a linear line defect comprising a plurality of defects that portions without the lattice elements;
an active region in the optical waveguide;
a recess in the active region;
an active substance in a liquid state accommodated in the recess, the active substance comprising fine particles of a four-level light-emitting material and a dispersion medium in which the fine particles are dispersed;
a light source configured to excite the active substance; and
an optical confinement structure configured to confine light in the active region, wherein the active region is interposed between the optical waveguide and the optical confinement structure.

16. The optical device according to claim 15, wherein the recess is on the base substrate in the active region.

17. The optical device according to claim 16, further comprising a flow path configured to supply the active substance into the recess.

18. The optical device according to claim 15, further comprising a temperature controller configured to control a temperature of the active substance.

19. The optical device according to claim 18, wherein:
the active region is provided in plural; and
the temperature controller is configured to control temperatures of the active substance in each of the active regions separately from one another.

20. A method of forming an optical device, the method comprising:
providing a plate-like photonic crystal main structure comprising a base substrate and a plurality of columnar lattice elements disposed in or on the base substrate, the lattice elements being periodically arranged at an interval not longer than a wavelength of a target light, and the lattice elements having a refractive index that is different from a refractive index of the base substrate;
providing an optical waveguide in the photonic crystal main structure, the optical waveguide comprising a linear line defect comprising a plurality of defects that are portions without the lattice elements;
providing an active region in the optical waveguide;
disposing an active substance in a liquid state in the active region, the active substance comprising a four-level light-emitting material;
providing a light source to excite the active substance; and
providing an optical confinement structure to confine light in the active region, wherein the active region is interposed between the optical waveguide and the optical confinement structure.

21. The method according to claim 20, wherein the active substance comprises fine particles of the four-level light-emitting material and a dispersion medium in which the fine particles are dispersed.

22. The method according to claim 20, further comprising providing a recess in the active region, wherein the active substance is accommodated in the recess.

23. The method according to claim 22, wherein the recess is on the base substrate in the active region.

24. The method according to claim 22, further comprising providing a flow path to supply the active substance into the recess.

25. The method according to claim 20, further comprising providing a temperature controller to control a temperature of the active substance.
